(19) United States
(12) Patent Application Publication
(10) Pub. No.: US 2016/0238945 A1
(43) Pub. Date: Aug. 18, 2016

(54) NOVEL PHOTORESIST STRIPPER AND APPLICATION PROCESS THEREOF

(71) Applicant: KEMPUR MICROELECTRONICS, INC., Beijing (CN)

(72) Inventors: Bing LI, Beijing (CN); Xin CHEN, Beijing (CN); Roger SINTA, Beijing (CN); Haibo LI, Beijing (CN); Xiaowei YU, Beijing (CN)

(21) Appl. No.: 14/902,420

(22) PCT Filed: Aug. 21, 2013
(86) PCT No.: PCT/CN2013/081929

§ 371 Date: Dec. 31, 2015

(30) Foreign Application Priority Data
Jul. 3, 2013 (CN) 201310276907.6

(51) Int. Cl. G03F 7/42; G03F 7/32; G03F 7/38; G03F 7/16; G03F 7/20

(52) U.S. Cl. CPC G03F 7/426; G03F 7/168; G03F 7/20; G03F 7/38; G03F 7/32; G03F 7/162

(57) ABSTRACT

A novel photoresist stripping liquid, used for removing superfluous photoresist on a substrate, comprises an organic solvent used for dissolving, a decrosslinking catalyst for accelerating stripping speed, and an anticorrosion agent for avoiding the substrate corrosion. The photoresist stripping liquid can shorten a stripping period, has no toxicity to human body and environment, and can thoroughly remove cross-linked photoresist after exposure, especially negative photoresist. In addition, the present invention also provides an application process of the photoresist stripping liquid. The process does not comprise heating and oscillation, thereby increasing the stripping speed and avoiding possible damage caused by auxiliary measures to the substrate.

### FIELD OF THE INVENTION

The present invention relates to a novel photoresist stripping liquid, used for removing superfluous photoresist and related application process, especially used for removing photoresist of lift-off process.

### PRIOR ART

The photoresist is a photosensitive material, and it is a mixed liquid consisting of the photosensitive resin, the photosensitizer and the solvent. Photocuring reaction can occur quickly in the exposed areas after the photosensitive resin by light, and the physical properties of this material are made to change significantly, particularly solubility and affinity. After the appropriate solvent processing, the soluble part will be dissolved, and the photoresist will form the desired image, which mainly applied to field of the microelectronics manufacturing. For example, in the semiconductor devices, the liquid crystal devices and the integrated circuits, it requires the use of photoresist coating, exposure, and a series of steps to complete the etching on the substrate, its role is to transferring the required pattern from the mask to the substrate. First, a photoresist is coated uniformly on the substrate (there are usually spin coating, slit coating, roller coating etc.); and the solvent of the photoresist is removed by pre-baking, so that the coated photoresist is dried; then, the light source with a specific wavelength is irradiated onto the photoresist through a mask coated on the substrate, and a chemical reaction reacts in the exposed areas of the photoresist, and it changes the rate of dissolution of the photoresist in the developer; then the corresponding pattern will be obtained by the developer (the photoresist left in the exposed areas after the exposure which forms insoluable material is the negative photoresist, on the contrary, the photoresist that becomes soluble material after the light exposure is the positive photoresist); then by etching, ion implantation or metal deposition process steps, the pattern will be transferred to the substrate unprotected by the photoresist, and finally the unnecessary photoresist is removed by the stripping liquid, the pattern transfer process is completed.

As can be seen by the above process, a photoresist etching step in the chip manufacturing process plays an auxiliary role, and after the completion of the etching pattern, the photoresist needs to be completely removed, so that to ensure that it is not present within the final product. For negative photoresist, the exposure process causes crosslinking of photoresist, so that it is insoluble in photographic developer, while also making it difficult to be removed in a subsequent stripping process; the other hand, in the transfer process of circuit, etching, ion implantation or metal deposition processes involve high temperatures or high energy processes, causing changes in the performance of the photoresist or photoresist containing other by-products, thereby making it difficult to be removed. The photoresist residue in the chip can affect the conductivity properties of circuit, or cannot reach during features designed, thereby resulting in failure of the product. How to effectively remove the photoresist, particularly the crosslinked negative photoresist or the photoresist that occurs chemical change after ion implantation process, becoming an important factor affecting chip yields and productivity.

The most of the photoresist in lift-off process is negative photoresist, which action principle is the crosslinking reaction of the photoresist in exposed areas, and the photoresist after crosslinking is insoluble in developer, while the photoresist after crosslinking form a mesh structure, it is difficult to be removed by a conventional stripping liquid. The conventional stripping liquid is organic solvent, such as acetone, isopropyl alcohol, N-methylpyrrolidone and the like. These organic solvents are good solvent for the photoresist, and have a more good solubility for the resin in the photoresist (phenol formaldehyde resin, poly-p-hydroxystyrene resin) and a photosensitizer (diazonaphthoquinone sulfonic acid ester, iodonium salt) and other components in photoresist, but a lower solubility for the photoresist formed the crosslinked structure, which requires the additional auxiliary measures, such as heating, ultrasonic concussion and the like. These process materials are not only high energy consumption, but have a certain degree of toxicity and harmfulness, and the auxiliary measures reduce the stripping rate, even may cause other defects for the pattern.

It discloses a stripping liquid which can better clean photoresist and residue in CN102012645, the stripping liquid can reduce the corrosion rate for the substrate and the wiring metal. The materials constituting of the photoresist stripping liquid are: hydrazine hydrate or organic amine compound, solvent, resist, pure water, the solvent contains dimethyl sulfoxide. Therefore, the stripping liquid is highly toxic for the operator and it is difficult to deal with the waste liquor. It describes a photoresist stripping liquid composition comprised by organic silicon compounds, acrylate copolymer and organic solvent in CN102147576. The organic silicon compounds in the photoresist stripping liquid composition are added as a surfactant, which weight control is more strict, if the content is too high, it is easy to foaming, as a result the substrate is difficult to be cleaned, if the content is too low, it would affect stripping property. Therefore, it is preferably 0.0005 to 1% by the total weight, but requires oscillation to achieve a comparatively ideal object. This step results in increasing the stripping time, and may cause defects of the substrate.

### DESCRIPTION OF THE INVENTION

The present invention aims to improve the above disadvantages, starting from the basic principles of photoresist, and provides a photoresist stripping liquid which has advantages such as a fast stripping rate, good effectiveness of stripping and environmental friendliness, and application process thereof.

In order to achieve the above object, the first aspect of the present invention provides a photoresist stripping liquid, which in addition to the total solvent that any solution itself must have, further comprising organic solvents, decrosslinking catalysts, anticorrosion agents and other additives. Wherein the main function of the organic solvents is dissolution, used for dissolve the product of crosslinking reaction from the photoresist after exposure, having good solubility for the product and promoting decrosslinking reaction, and it requires better solubility for subject film-forming resin of the photoresist, while it has a high boiling point and environment-friendly; decrosslinking catalysts are used to catalyze the decrosslinking reaction, reduce the activation energy of decrosslinking reaction, and accelerate the rate of decrosslinking reaction, making the photoresist desired to be removed to be dissolved preferably in solvent and completely stripped as much as possible; the main function of anticorrosion agents is to protect the substrate materials that will not be etched by solvent or catalyst, which mechanism is that a protective film of complex compounds is formed with the substrate materials, so that reducing the corrosive to the substrate materials by the stripping liquid, particularly metal substrate materials.

The total solvent of the said solution is generally dimethyl sulfoxide, N-methyl pyrrolidone or a mixture of more than one thereof. In addition to making other ingredients to mix preferably, the total solvent also has better solubility to photoresist stripping liquid, and helps the photoresist to be removed preferably. It accounts for the weight percentage of 65˜78%.

The said organic solvents preferably are good solvents for phenol resins, and may be a single solvent, or a mixture of two or more solvents listed below: for example ketones, such as acetone, methyl ethyl ketone, cyclohexanone, methyl isoamyl ketone, 2-heptanone, cyclohexanone and the like; polyols and derivatives thereof, such as 1,2-ethylene glycol, diethylene glycol, propylene glycol, ethylene glycol monoethyl ether, propylene glycol monomethyl ether, diethylene glycol monoethyl ether, ethylene glycol monoethyl ether acetate, propylene glycol monomethyl ether acetate; ring ethers, such as tetrahydrofuran, dioxane; esters, such as methyl lactate, ethyl lactate, methyl acetate, ethyl acetate, butyl acetate, methyl pyruvate, ethyl pyruvate, methyl methoxy propionate, ethyl ethoxy propionate, γ-butyrolactone; amines, such as dimethylformamide, N-methylacetamide, N-methylpyrrolidone and the like.

Based on the total weight of the said mixed solution, the content of the organic solvent in the photoresist stripping liquid of the present invention is preferably accounted for 20 to 30% of the total weight, so that the photoresist desired to be removed can be dissolved preferably.

The said decrosslinking catalyst is preferably organic weak acid catalyst, and more preferably organic dibasic acid, such as oxalic acid, malonic acid, terephthalic acid, benzoic acid, benzenesulfonic acid and the like.

Preferably, the content of the decrosslinking catalyst is more than 0, and is accounted for 0 to 8% of the total weight of the photoresist stripping liquid, and more preferably 4 to 6%. If the content is too low, the crosslinking photoresist can't be decomposed completely, but also can't be removed completely or the rate of stripping is low.

The said anticorrosion agent is preferably a material having two or more coordination centers, which can form complex compounds with metal ions, such as oxalic acid, acetyl acetone, 2,2′-bipyridine, ethylenediamine and so on.

The content of the anticorrosion agent is preferably accounted for 0.05 to 2% of the total weight of the stripping liquid, and more preferably 0.5 to 1.5% by the total weight. In any of the above schemes, it is preferred that pure water is deionized water with resistance of at least 18 MΩ.

Furthermore, in order to achieve the above object, the second aspect of the present invention provides a technological process of applying the photoresist stripping liquid, namely: a method of stripping a photoresist from substrate material, comprising the following steps:
1. Coating the conductive metal film or the insulating film formed on a substrate with photoresist;
2. The substrate coated by photoresist is through the steps of soft bake, exposure, PEB, and development, then a photoresist pattern is formed on the substrate;
3. By the process steps of etching, ion implantation or metal deposition etc., the patterning will be transferred to the substrate without protected by photoresist;
4. Placing the photoresist stripping liquid provided in accordance with the first aspect of the present invention into the stripping tank, heating to a suitable temperature and keep constant temperature;
5. The substrate to be removed photoresist is infiltrated in the stripping liquid at a constant temperature in a certain time and then taken out;
6. Rinsing the substrate with rinsing fluid and drying, to stripping the photoresist completely; and
7. Observing the substrate surface under a microscope or a scanning electron microscope (SEM), and confirming no photoresist residue.

In order to achieve a better effect of stripping, the stripping process needs to be optimized, as follows:

In the steps using the photoresist stripping liquid as described above to remove excess photoresist, preferably, in the step 1, the substrate is silicon plate or sheet metal.

In any of the above schemes, preferably, in the step 1, the way of coating the photoresist may be roller coating, blade coating, spin coating, etc.

In any of the above schemes, more preferably, in the step 1, the way of coating the photoresist is spin coating.

In any of the above schemes, preferably, in the step 4, the photoresist stripping liquid is heated to 50-70° C.

In any of the above schemes, more preferably, in the step 4, the photoresist stripping liquid is heated to 70° C.

In any of the above schemes, preferably, in the step 5, the substrate in the stripping liquid keeps constant temperature for 5-40 min.

In any of the above schemes, preferably, in the step 5, the substrate in the stripping liquid keeps constant temperature for 20-30 min, more preferably 30 min.

In any of the above schemes, preferably, in the step 6, the substrate is removed from the stripping liquid and immersed in an organic solvent for a certain time, the step is optional, which may be used to accelerate the cleaning speed of silicon wafer.

In any of the above schemes, preferably, in the step 6, the substrate is placed in the organic solvent for a certain time, and more preferably, the said organic solvent is an organic solvent compatible with water, such as isopropanol.

In any of the above schemes, preferably, in the step 6, preferably immersed in an organic solvent tank for 5 min.

In any of the above schemes, preferably, in the step 7, the deionized water is used to rinse the substrate, and after washing, drying the substrate by blowing-dry with nitrogen or shaking-dry by rotary manner.

The photoresist stripping liquid of the present invention contains decrosslinking catalysts, so it can efficiently catalyze the decrosslinking reaction of the crosslinking type negative photoresist and remove the photoresist quickly and efficiently, and the photoresist of the present invention contains anticorrosion protection agent that protects the metal substrate material, which can effectively prevent the stripping liquid from corroding the substrate material, to ensure the stability of the process; and then, the photoresist stripping liquid in accordance with the present invention used with a simple process, it does not require ultrasound oscillation and scraping film process, saving processing time, and it is possible to improve productivity and to avoid possible damage caused by the auxiliary process; finally, the photoresist stripping liquid of the present invention is used with high boiling point, environmentally friendly solvents, can reduce environmental pollution and damage to human body.

### DESCRIPTION OF FIGURES

FIG. 1 is the flow diagram of the application process of a preferred embodiment of a novel photoresist stripping liquid according to the present invention.

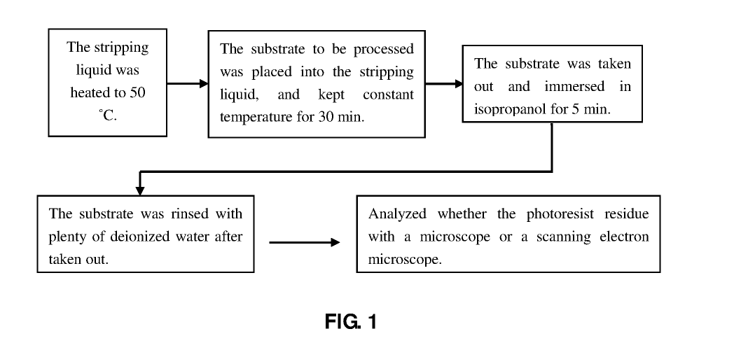

### EXAMPLES

In conjunction with the drawings and specific embodiments, the present invention will be further described below.

### Comparative Example-1

The acetone solvent was placed in the stripping tank, maintaining the temperature at 23° C., and then the substrate to be processed (aluminum) was placed into acetone solvent in the stripping tank for 5 min. Then the substrate was taken out and observed the photoresist residue situation with a microscope.

### Comparative Example-2

Taken 70 g dimethylsulfoxide, 29 g N-methylacetamide and 1 g ethylenediaminetetraacetic acid (EDTA) were added. After mixed fully, a desired photoresist stripping liquid was prepared by pressuring and filtrating with 0.1 um disposable filter disposable filter or filter membrane.

### Comparative Example-3

Taken 70 g dimethylsulfoxide, 25 g N-methylacetamide was added, and then 5 g oxalic acid was added. After mixed fully, a desired photoresist stripping liquid was prepared by pressuring and filtrating with 0.1 um disposable filterdisposable filter or filter membrane.

### Example-4

Taken 70 g dimethylsulfoxide, 24 g N-methylacetamide was added, and then 5 g oxalic acid and 1 g ethylenediaminetetraacetic acid (EDTA) were added. After mixed fully, a desired photoresist stripping liquid was prepared by pressuring and filtrating with 0.1 um disposable filterdisposable filter or filter membrane.

In 2-4 examples described above, the well-mixed sample was placed in the stripping tank, and then the photoresist stripping liquid was removed according to the technological process indicated by the accompanying drawing 1. Preferably, heated to 50° C., the substrate to be processed (aluminum) was placed into the stripping liquid in the stripping tank, and kept constant temperature for 30 min. Then the substrate was taken out and immersed in isopropanol for 5 min. And then the substrate was rinsed with plenty of deionized water after taken. Finally, observed whether the photoresist residue with a microscope.

For 1 to 4 examples, took the sample from the stripping liquid processing the substrate before and after, and carried out the metal ion content test, in order to testing the corrosive of the stripping liquid to the metal substrate material.

| | the content of Al (ppb) | | the photoresist | the processing |
|---|---|---|---|---|
| Example | Before | after | residue | temperature (° C.) |
| 1 | 157.8 | 168.1 | plenty of | 23 |
| 2 | 248.4 | 271.8 | a little of | 50 |
| 3 | 220.0 | 989.2 | No | 50 |
| 4 | 286.7 | 300.3 | No | 50 |

As seen by the above experiments, the photoresist stripping liquid containing the decrosslinking catalyst and the anticorrosion agent according to the present invention has a good effect of the stripping at higher temperatures, and no photoresist remained on the substrate. Meanwhile in metal impurities, the aluminum content changes very little, indicating that the substrate material does not be hurt, almost no corrosion.

### Example-5

Taken 68 g dimethylsulfoxide, 27 g N-methylacetamide was added, and then 4 g oxalic acid and 1 g ethylenediaminetetraacetic acid (EDTA) were added. After mixed fully, a desired photoresist stripping liquid was prepared by pressuring and filtrating with 0.1 um disposable filter or filter membrane.

In this example, the well-mixed sample was placed in the stripping tank, and then preferably, it was heated to 70° C. The substrate to be processed was placed into the stripping liquid in the stripping tank, and kept constant temperature for 20 min. Then the substrate was taken out and immersed in isopropanol for 5 min. And then the substrate was rinsed with plenty of deionized water after taken. Finally, observed whether the photoresist residue with a microscope.

### Example-6

Taken 74 g dimethylsulfoxide, 20 g N-methylacetamide was added, and then 4 g oxalic acid and 1 g ethylenediaminetetraacetic acid (EDTA) were added. After mixed fully, a desired photoresist stripping liquid was prepared by pressuring and filtrating with 0.1 um disposable filter or filter membrane.

In this example, the well-mixed sample was placed in the stripping tank, and then preferably, it was heated to 70° C. The substrate to be processed was placed into the stripping liquid in the stripping tank, and kept constant temperature for 15 min. Then the substrate was taken out and immersed in isopropanol for 5 min. And then the substrate was rinsed with plenty of deionized water after taken. Finally, observed whether the photoresist residue with a microscope.

### Example-7

Taken 70 g dimethylsulfoxide, 25 g N-methylacetamide was added, and then 4 g oxalic acid and 1 g ethylenediaminetetraacetic acid (EDTA) were added. After mixed fully, a desired photoresist stripping liquid was prepared by pressuring and filtrating with 0.1 um disposable filter or filter membrane.

In this example, the well-mixed sample was placed in the stripping tank, and then preferably, it was heated to 60° C. The substrate to be processed was placed into the stripping liquid in the stripping tank, and kept constant temperature for 15 min. Then the substrate was taken out and immersed in isopropanol for 5 min. And then the substrate was rinsed with plenty of deionized water after taken. Finally, observed whether the photoresist residue with a microscope.

### Example-8

Taken 65 g dimethylsulfoxide, 28 g N-methylacetamide was added, and then 5 g oxalic acid and 2 g ethylenediaminetetraacetic acid (EDTA) were added. After mixed fully, a desired photoresist stripping liquid was prepared by pressuring and filtrating with 0.1 um disposable filter or filter membrane.

In this example, the well-mixed sample was placed in the stripping tank, and then preferably, it was heated to 67° C. The substrate to be processed was placed into the stripping liquid in the stripping tank, and kept constant temperature for 25 min. Then the substrate was taken out and immersed in isopropanol for 5 min. And then the substrate was rinsed with plenty of deionized water after taken. Finally, observed whether the photoresist residue with a microscope.

### Example-9

Taken 68 g dimethylsulfoxide, 25 g N-methylacetamide was added, and then 6 g oxalic acid and 1 g ethylenediaminetetraacetic acid (EDTA) were added. After mixed fully, a desired photoresist stripping liquid was prepared by pressuring and filtrating with 0.1 um disposable filter or filter membrane.

In this example, the well-mixed sample was placed in the stripping tank, and then preferably, it was heated to 54° C. The substrate to be processed was placed into the stripping liquid in the stripping tank, and kept constant temperature for 28 min. Then the substrate was taken out and immersed in isopropanol for 5 min. And then the substrate was rinsed with plenty of deionized water after taken. Finally, observed whether the photoresist residue with a microscope.

### Example-10

Taken 78 g dimethylsulfoxide, 20 g N-methylacetamide was added, and then 1.9 g oxalic acid and 0.1 g ethylenediaminetetraacetic acid (EDTA) were added. After mixed fully, a desired photoresist stripping liquid was prepared by pressuring and filtrating with 0.1 um disposable filter or filter membrane.

In this example, the well-mixed sample was placed in the stripping tank, and then preferably, it was heated to 70° C. The substrate to be processed was placed into the stripping liquid in the stripping tank, and kept constant temperature for 30 min. Then the substrate was taken out and immersed in isopropanol for 5 min. And then the substrate was rinsed with plenty of deionized water after taken. Finally, observed whether the photoresist residue with a microscope.

In 1-10 examples described above, preferably, the photoresist to be removed on the substrate is negative photoresist.

### Example-11

Taken 70 g dimethylsulfoxide, 24 g N-methylacetamide, 5 g oxalic acid and 1 g ethylenediaminetetraacetic acid (EDTA) were added. After mixed fully, a desired photoresist stripping liquid was prepared by pressuring and filtrating with 0.1 um disposable filter.

In this example, the well-mixed sample was placed in the stripping tank, and then preferably, it was heated to 40° C. The substrate to be processed was placed into the stripping liquid in the stripping tank, and kept constant temperature for 5 min. Then the substrate was taken out and immersed in isopropanol for 1 min. And then the substrate was rinsed with plenty of deionized water after taken. Finally, observed whether the photoresist residue with a microscope.

In this example, preferably, the photoresist to be removed on the substrate is positive photoresist.

### Comparative Example-12

The acetone solvent was placed in the stripping tank, maintaining the temperature at 23° C., and then the substrate to be processed was placed into acetone solvent in the stripping tank for 2 min. Then the substrate was taken out and observed the photoresist residue situation with a microscope.

In this example, preferably, the photoresist to be removed on the substrate is positive photoresist.

For the positive photoresist, embodiment 11 used much shorter time and removed more completely compared with embodiment 12, and because the acetone is easily inhaled by human bodies and causes harmfulness. Therefore, the photoresist stripping liquid provided by the present invention is obviously more advantageous.

Finally, it should be noted that: the above embodiments are merely provided for describing the technical solutions of the present invention, not intended to limit; it still can be modified to the above technical solutions described in the embodiments, or for some technical features equivalent replacements; the technical solutions of a novel photoresist stripping liquid and application process thereof provided by the present invention include any combination of the above-mentioned parts, simple changes in the respective part of the assembly, replacement or combination remains in the scope of the present invention.

1. A photoresist stripping liquid, the said photoresist stripping liquid comprises total solvent, organic solvents, decrosslinking catalysts, anticorrosion agents and other additives.

2. The photoresist stripping liquid according to claim 1, wherein the said total solvent is dimethyl sulfoxide or N-methyl pyrrolidone.

3. The photoresist stripping liquid according to claim 2, wherein the said total solvent accounts for the weight percentage of 65˜78%.

4. (canceled)

5. The photoresist stripping liquid according to claim 1, wherein the said organic solvents are selected from one of the group consisting of ketones, polyols and derivatives thereof, ring ethers, esters, amines, or mixtures of more than one thereof.

6. (canceled)

7. (canceled)

8. (canceled)

9. (canceled)

10. (canceled)

11. The photoresist stripping liquid according to claim 4, wherein the said the content of the organic solvents is accounted for 20 to 30% of the total weight of the photoresist stripping liquid.

12. (canceled)

13. The photoresist stripping liquid according to claim 1, wherein the said decrosslinking catalysts are organic dibasic acid.

14. The photoresist stripping liquid according to claim 13, wherein the said organic dibasic acid is at least one of oxalic acid, malonic acid, terephthalic acid, benzoic acid, benzenesulfonic acid.

15. (canceled)

16. The photoresist stripping liquid according to claim 15, wherein the content of the said decrosslinking catalysts is accounted for 4 to 6% of the total weight of the photoresist stripping liquid.

17. (canceled)

18. The photoresist stripping liquid according to claim 1, wherein the said anticorrosion agents are at least one of oxalic acid, acetyl acetone, 2,2′-bipyridine, ethylenediamine.

19. (canceled)

20. The photoresist stripping liquid according to claim 18, wherein the content of the said anticorrosion agents is accounted for 0.5 to 1.5% by the total weight of the photoresist stripping liquid.

21. An application process of the photoresist stripping liquid, comprising the following steps:
1) coating the conductive metal film or the insulating film formed on a substrate with photoresist;
2) by the steps of softbake, exposure, PEB, and development a photoresist pattern is formed on the substrate;
3) by the process steps of etching, ion implantation or metal deposition etc., the patterning will be transferred to the substrate without protected by photoresist;
4) placing the photoresist stripping liquid said in claims 1˜10 into the stripping tank, heating to a suitable temperature and keeping constant temperature;
5) the substrate with photoresist is immersion in the stripping liquid at a constant temperature and then taken out;
6) rinsing the substrate with rinsing fluid and drying, to stripping the photoresist completely; and
7) observing the substrate surface under a microscope or a scanning electron microscope (SEM), and confirming no photoresist residue.

22. An application process of the photoresist stripping liquid according to claim 21, wherein in the step 1, the said substrate is substrate material containing metals.

23. (canceled)

24. An application process of the photoresist stripping liquid according to claim 21, wherein in the step 1, the way of coating the photoresist is anyone of roller coating, slit coating, spin coating.

25. An application process of the photoresist stripping liquid according to claim 21, wherein in the step 4, the photoresist stripping liquid is heated to 50-70° C., and then kept constant temperature.

26. (canceled)

27. (canceled)

28. An application process of the photoresist stripping liquid according to claim 21, wherein in the step 5, the said substrate in the said constant temperature stripping liquid keeps constant temperature for 5-40 min.

29. (canceled)

30. (canceled)

31. An application process of the photoresist stripping liquid according to claim 21, wherein in the step 6, the said substrate is removed from the stripping liquid before rinsing with rinsing liquid and immersed in an organic solvents.

32. (canceled)

33. An application process of the photoresist stripping liquid according to claim 31, wherein the said organic solvents are at least one of ethanol, ethylene glycol, isopropanol, acetone.

34. An application process of the photoresist stripping liquid according to claim 31, wherein the said substrate is immersed for 0˜10 min.

35. (canceled)

36. An application process of the photoresist stripping liquid according to claim 21, wherein in the step 6, the rinsing liquid is deionized water.

37. (canceled)

38. An application process of the photoresist stripping liquid according to claim 21, wherein in the step 6, the way of drying the substrate is blowing-dry with nitrogen or shaking-dry by rotary manner.
